(19) United States
(12) Patent Application Publication
(10) Pub. No.: US 2014/0001504 A1
(43) Pub. Date: Jan. 2, 2014

(54) LIGHT EMITTING DIODE PACKAGE AND METHOD FOR MANUFACTURING THE SAME

(71) Applicant: ADVANCED OPTOELECTRONIC TECHNOLOGY, INC., Hsinchu Hsien (TW)

(72) Inventor: HOU-TE LIN, Hsinchu (TW)

(73) Assignee: ADVANCED OPTOELECTRONIC TECHNOLOGY, INC., Hsinchu Hsien (TW)

(21) Appl. No.: 13/900,619

(22) Filed: May 23, 2013

(30) Foreign Application Priority Data
Jun. 29, 2012 (CN) 2012102209012

(51) Int. Cl. H01L 33/60; H01L 33/52

(52) U.S. Cl. CPC H01L 33/60; H01L 33/52
USPC 257/98; 438/27

(57) ABSTRACT

An LED package includes a substrate, a pair of electrodes connected to the substrate, an LED die electrically connected to the electrodes, an encapsulation formed on the substrate to cover the LED die, and a reflective cup surrounding the substrate and the encapsulation. A curved surface is formed on the reflective cup, and abuts against and protrudes towards the encapsulation. The present disclosure also provides a method for manufacturing the LED package described above.

### BACKGROUND

1. Technical Field

The present disclosure generally relates to a light emitting diode (LED) package and method for manufacturing the same, and particularly to an LED package which has a reflective cup and a method for manufacturing the same.

2. Description of Related Art

In recent years, light emitting diodes (LEDs) have increasingly been used as substitutes for incandescent bulbs, compact fluorescent lamps and fluorescent tubes as light sources of illumination devices.

The LED package generally includes a substrate, a pair of electrodes formed on the substrate, and an LED die arranged on the substrate and electrically connected to the electrodes. A reflective cup is usually provided to surround the LED die to improve light effect output. Light emitting from the LED die strikes a reflective surface of the reflective cup and is reflected at an angle. However, the reflective surface of the reflective cup is usually an inclined plane or a vertical plane in a small sized LED package, which undesirably limits the angle of the light output.

Therefore, what is needed is to provide an LED package and method for manufacturing the same which can overcome the above shortcomings.

### BRIEF DESCRIPTION OF THE DRAWINGS

Many aspects of the disclosure can be better understood with reference to the following drawings. The components in the drawings are not necessarily drawn to scale, the emphasis instead being placed upon clearly illustrating the principles of the disclosure.

FIG. 1 is a schematic, cross-sectional view of one embodiment of an LED package.

FIG. 2 is a top view of the LED package of FIG. 1.

FIG. 3 is a bottom view of the LED package of FIG. 1.

FIGS. 4-14 are schematic cross-sectional views showing the processes of the method for manufacturing the LED package of FIG. 1.

### DETAILED DESCRIPTION

Reference will now be made to the drawings to describe the present LED packages, and a method for manufacturing the LED packages, in detail.

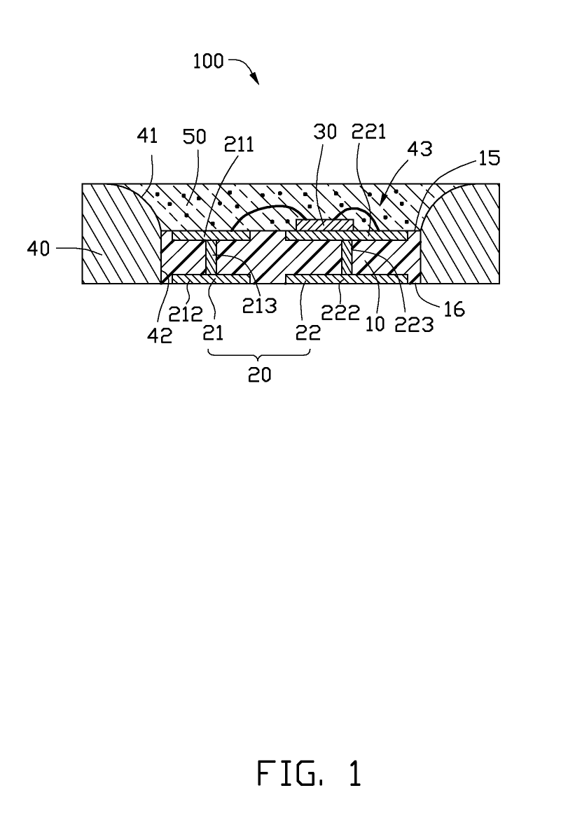

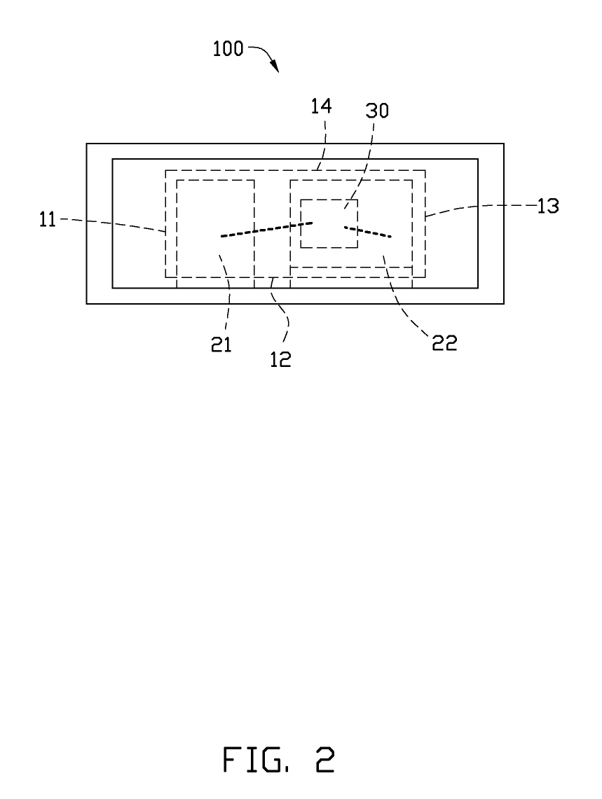

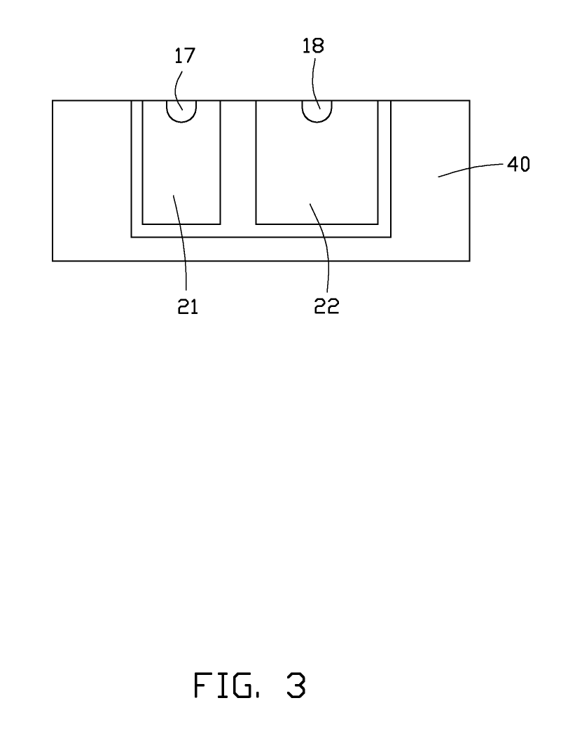

Referring to FIGS. 1-3, an LED package 100 includes a substrate 10, two electrodes 20, an LED die 30, a reflective cup 40, and an encapsulation 50. The two electrodes 20 are formed on the substrate 10 and spaced from each other. The LED die 30 is mounted on the substrate 10 and electrically connected to the electrodes 20. The reflective cup 40 surrounds the LED die 30. The encapsulation 50 covers the LED die 30 on the substrate 10.

The substrate 10 is substantially plate-shaped. The substrate 10 includes a first sidewall 11, a second sidewall 12, a third sidewall 13, and a fourth sidewall 14. The first sidewall 11 is opposite to the third sidewall 13. The second sidewall 12 forms a step protruding outwardly from a lower portion thereof. The second sidewall 12 has a top edge located within the reflective cup 40 and spaced from a corresponding lateral top edge of the reflective cup 40, and a bottom edge linear with a corresponding lateral bottom edge of the reflective cup 40. The second sidewall 12 is opposite to the fourth sidewall 14. The substrate 10 also includes two surfaces, namely an upper surface 15 and a lower surface 16. The two surfaces 15, 16 are located at two opposite ends of the four sidewalls 11, 12, 13, 14. The two surfaces 15, 16 can be opposite and substantially parallel to each other. The upper surface 15 is used for supporting the LED die 30. In the embodiment, a first recess 17 and a second recess 18 are recessed from the second sidewall 12 towards the fourth sidewall 14 and extend through the upper surface 15 and the lower surface 16. In other words, the first and second recesses 17, 18 penetrate the upper surface 15 and the lower surface 16 of the substrate 10.

The electrodes 20 include a first electrode 21 and a second electrode 22 spaced from the first electrode 21. The first and second electrodes 21, 22 extend from the upper surface 15 to the lower surface 16 of the substrate 10. The first electrode 21 has an upper pad 211 covering an end of the first recess 17 on the upper surface 15, and the second electrode 22 has an upper pad 221 covering an end of the second recess 18 on the upper surface 15, thereby providing more space for wire bonding process on the upper surface 15 of the LED die 30. The first electrode 21 and the second electrode 22 each includes a lower pad 212, 222 substantially parallel to the upper pad 211, 221, and a vertical pole 213, 223 interconnecting the upper pad 211, 221 and the lower pad 212, 222. The vertical poles 213, 223 of the first electrode 21 and the second electrode 22 are spaced from the first recess 17 and the second recess 18. The first and second recesses 17, 18 penetrate the lower surface 16 and further penetrate the lower pads 212, 222, but do not penetrate the upper pads 211, 221. When the LED package 100 is employed as a side view light source, a lateral face of the step of the second sidewall 12 of the substrate 10 is connected to a circle board (not illustrated). The first and second recesses 17, 18 can be filled with solder to electrically connect the upper pads 211, 221 of the first electrode 21 and the second electrode 22 with the circuit board. Alternatively, the first and second recesses 17, 18 can be omitted when the LED package 100 is not employed as a side view light source. The lower surface 16 of the substrate 10 is electrically connected to the circuit board.

The LED die 30 is arranged on the upper surface 15 of the substrate 10 and electrically connected to the electrodes 20. The LED die 30 can be mounted by flip chip bonding, wire bonding, or eutectic bonding. In the embodiment, the LED die 30 is mounted on one electrode 20 by wire bonding with the first electrode 21 and the second electrode 22.

The reflective cup 40 surrounds the substrate 10 and the LED die 30. The reflective cup 40 includes a reflecting surface 41 and a connecting surface 42 extending downwardly from the reflecting surface 41. The reflecting surface 41 is positioned above the substrate 10 and surrounds the LED die 30. The reflecting surface 41 is a curved surface, protruding towards the LED die 30 and extending from the upper surface 15 of the substrate 10 upwardly and away from the LED die 30. The reflecting surface 41 can be a convex surface. The connecting surface 42 is flat and firmly attached to the four sidewalls of the substrate 10. A receiving space 43 is defined above the substrate 10 and surrounded by the reflective cup 40.

The encapsulation 50 is filled in the receiving space 43 of the reflective cup 40 and covers the LED die 30. Phosphor power can be suspended in the encapsulation 50. The reflective cup 40 covers both of the substrate 10 and the encapsulation 50, so the reflective cup 40 also covers gaps between the substrate 10 and the encapsulation 50. Thus, moisture and dust can be prevented from infiltrating into the LED package 100.

In the present LED package 100, part of light emitted from the LED die 30 emits out of the LED package 100 directly, the other part of the light strikes on the reflecting surface 41 of the reflective cup 40 at lateral sides of the LED die 30, and then emits out from the encapsulation 50. The reflecting surface 41 can result in a special light field. Further, the first and second recesses 17, 18 defined in the second sidewall 12 of the substrate 10 can receive solder for welding, which makes the electrical connection of the light source and the circuit board versatile.

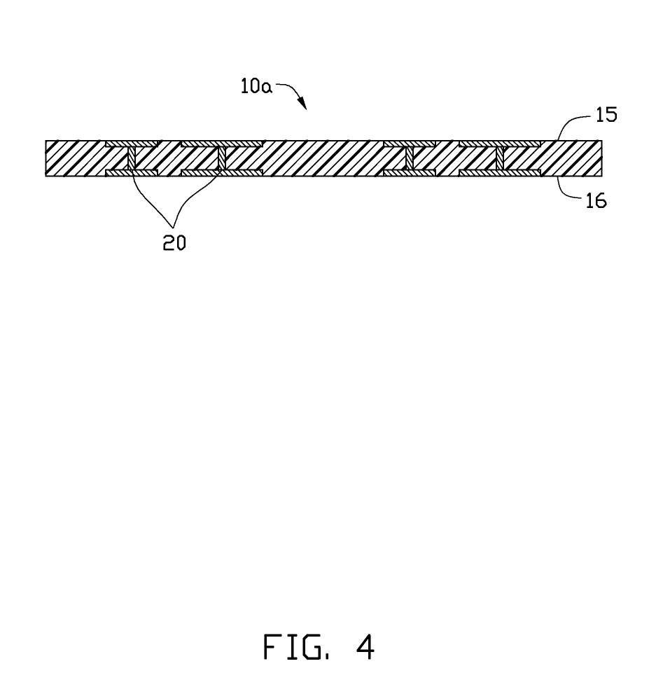

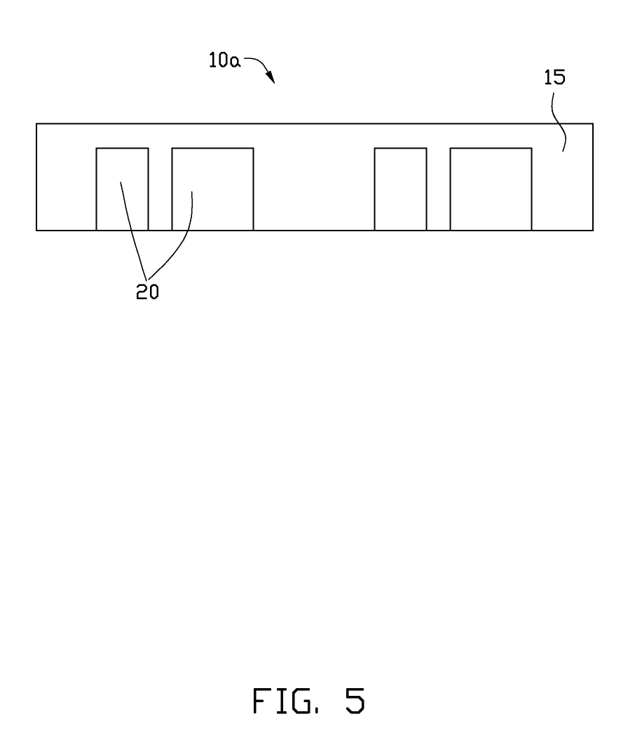

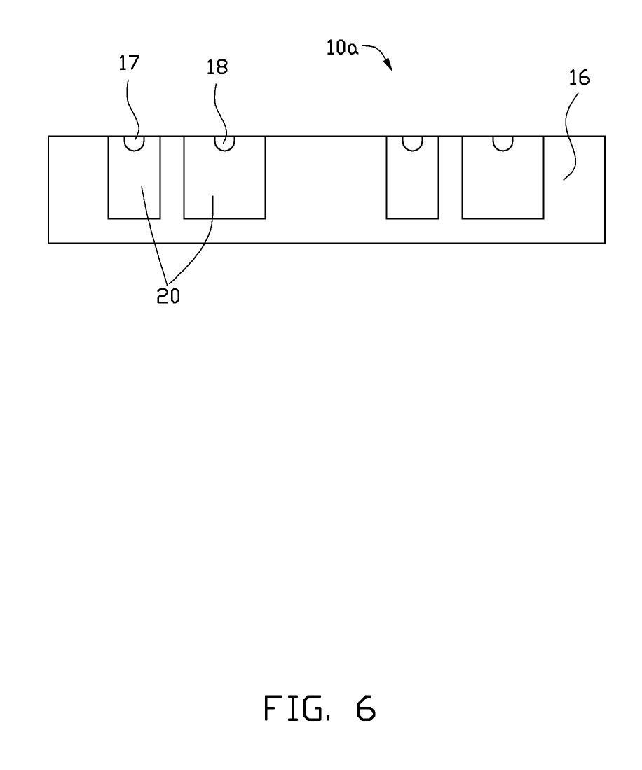

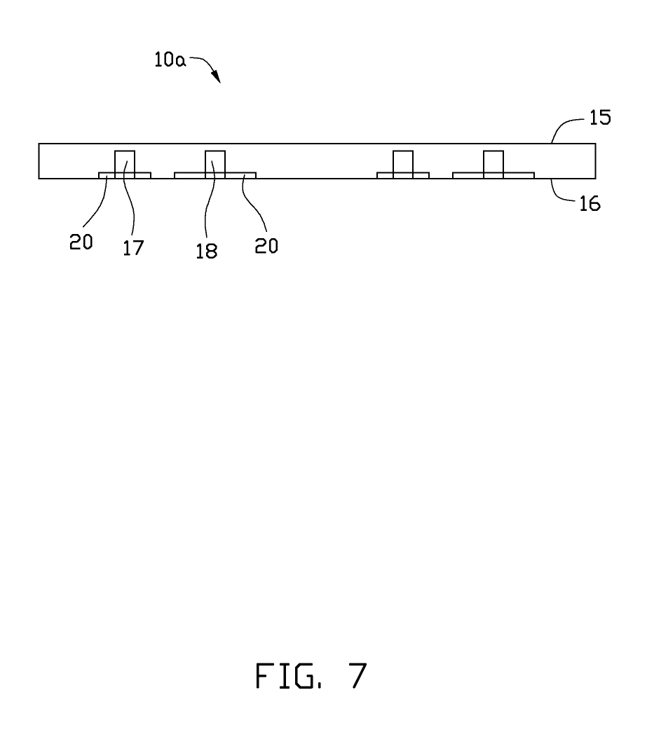

Referring to FIGS. 4-14, one embodiment of a method for manufacturing the LED package 100 includes the following steps.

Step 1: providing a supporting board 10a having an upper surface 15 and a lower surface 16, forming a plurality of pairs of electrodes 20 in the supporting board 10a, and defining a plurality of first recesses 17 and a plurality of second recesses 18 at a lateral side of the supporting board 10a;

Step 2: electrically connecting a plurality of LED dies 30 to the electrodes 20;

Step 3: forming an encapsulation 50 to cover the LED dies 30 on the supporting board 10a;

Step 4: defining a plurality of depression portions 70 extending from the lower surface 12 to an upper surface 11 of the encapsulation 50;

Step 5: forming reflective cups 40a in the depression portions 70;

Step 6: cutting the reflective cups 40a to form individual LED packages 100, wherein each LED package 100 has a reflecting surface 41 facing the LED die 30 thereof.

In step 1, referring to FIGS. 4-7, each pair of the first recess 17 and the second recess 18 are spaced from each other. The supporting board 10a is substantially plate-shaped and can be made of high polymer materials or composite materials. The electrodes 20 are formed on the upper surface 15 and the lower surface 16 through the supporting board 10a. Each electrode 20 is spaced from the other in each pair. Each pair of electrodes 20 is spaced from an adjacent pair. The electrodes 20 cover the first recesses 17 and the second recesses 18 on the upper surface 11, with the recesses 17, 18 extending through the lower surface 12.

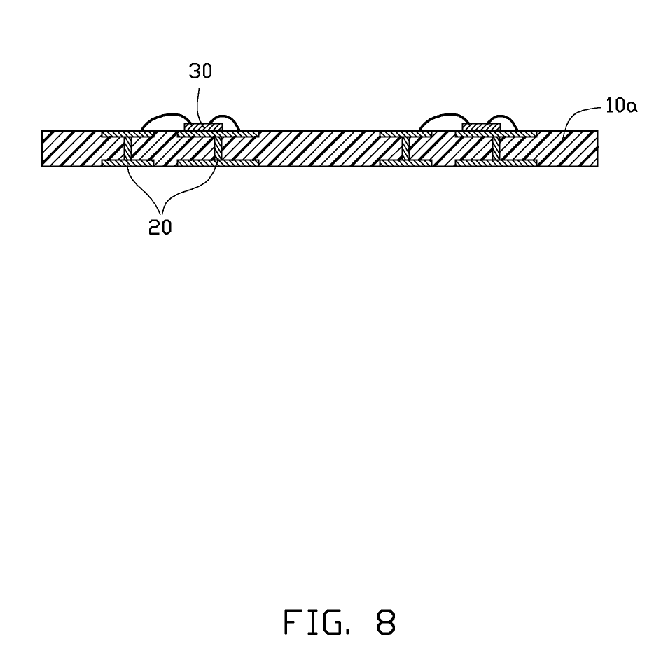

In step 2, referring to FIG. 8, there are two LED dies 30 mounted on the supporting board 10a. Each LED die 30 is electrically connected to the electrodes 20 by wire bonding.

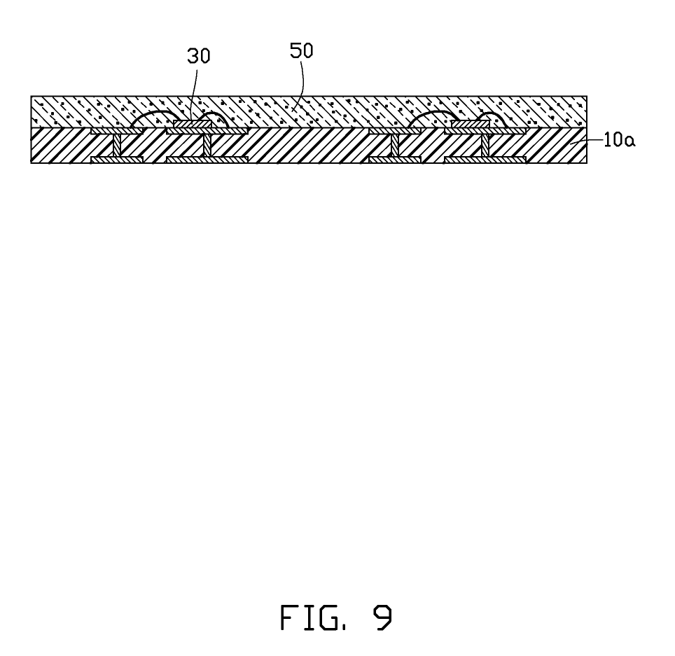

In step 3, referring to FIG. 9, the encapsulation 50 can be formed by injection molding or compression molding.

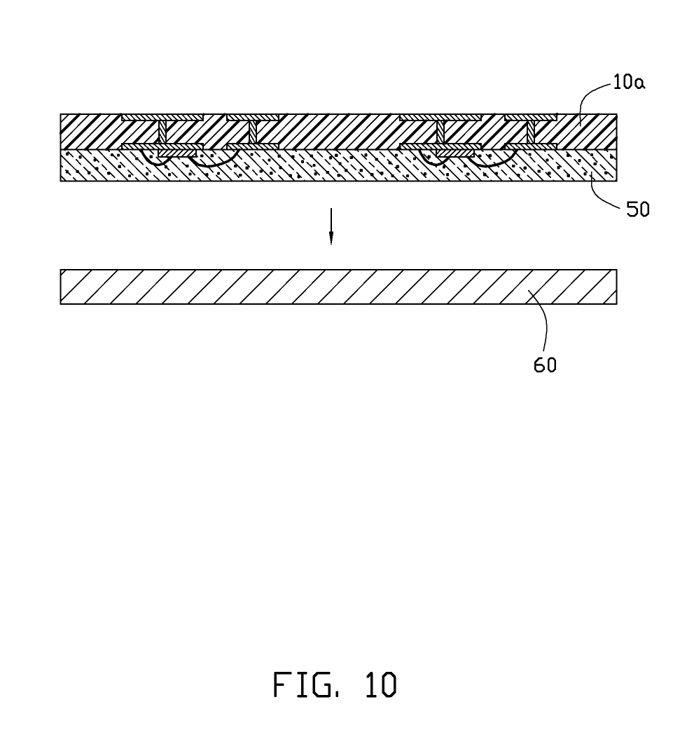

Referring to FIG. 10, before the step of defining a plurality of depression portions 70, a step of covering a buffer plate 60 on the encapsulation 50 is performed. The buffer plate 60 is attached on the upper surface 15 of the supporting board 10a. During the attaching process, the supporting board 10a is reversed, and the buffer plate 60 is attached onto the encapsulation 50 downwardly.

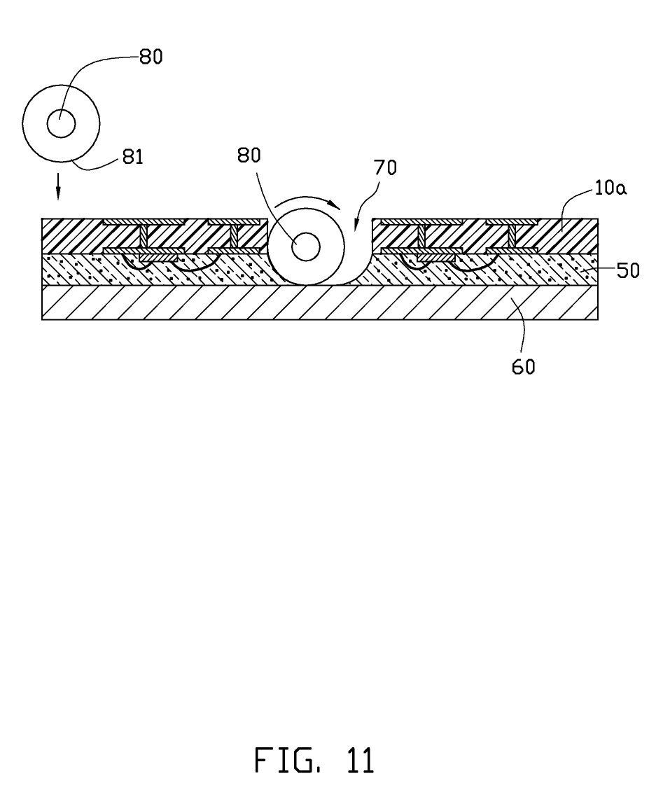

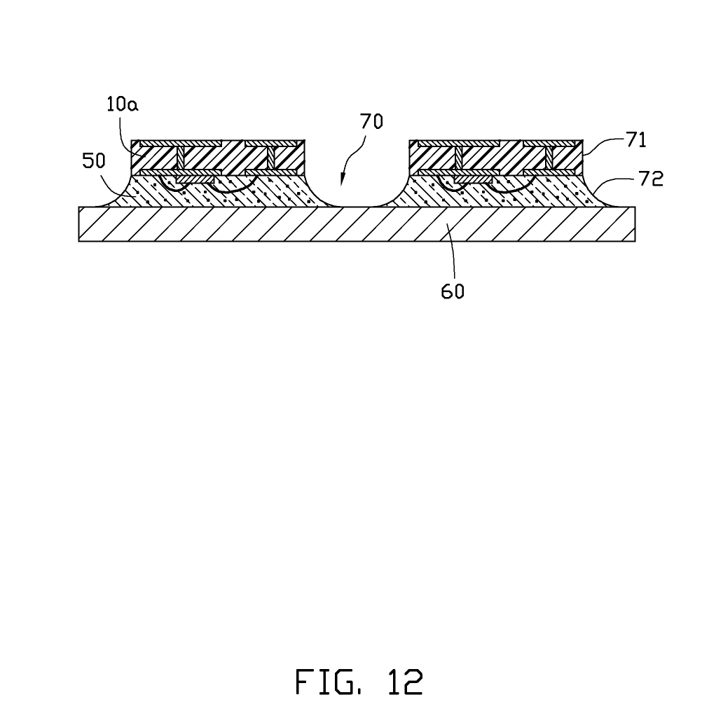

In step 4, referring to FIGS. 11-12, a mold 80 is provided. The mold 80 has a curved surface 81 protruding downwardly. In the embodiment, the mold 80 is a cylinder hob. The curved surface 81 can be a convex surface. The mold 80 is positioned between the two adjacent electrodes 20 and faces the lower surface 16 of the supporting board 10a.

The mold 80 drills the supporting board 10a and the encapsulation 50 from the lower surface 16 of the supporting board 10a to the buffer plate 60, forming the depression portions 70 therein. When the mold 80 contacts the buffer plate 60, the movement of the mold 80 is stopped and then removed from the depression portion 70. A flat broken surface 71 is formed in the supporting board 10a because the mold 80 moves in a substantially straight and downwardly direction. A curved broken surface 72 is formed in the encapsulation 50 because the curved surface 81 of the mold 80 is stopped therein. Alternatively, the mold 80 can move along a direction substantially parallel to the supporting board 10a to enlarge a width of the depression portion 70. Other depression portions 70 can be formed as the process described above. A precision of the surfaces of the depression portions 70 can be high because a precision of the mold 80 is easy to control.

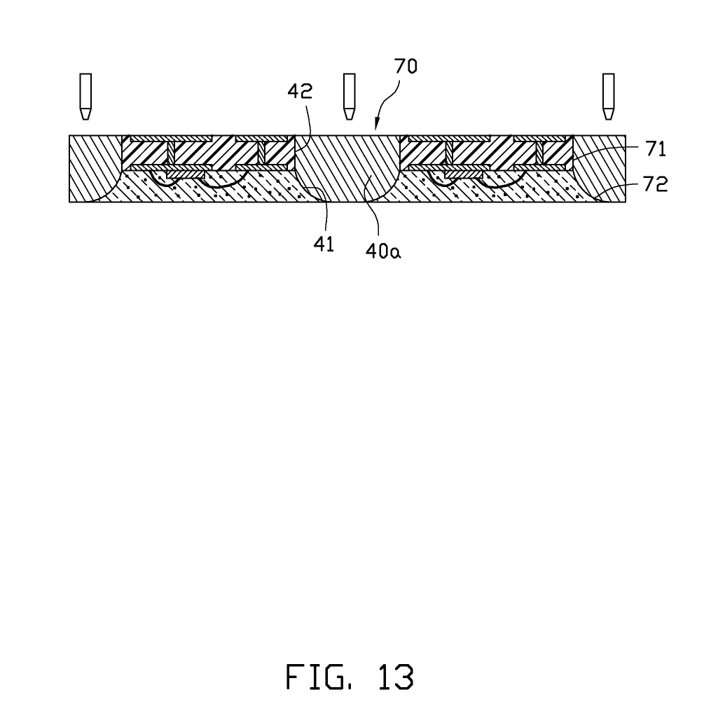

In step 5, referring to FIG. 13, the reflective cups 40 are formed in the depression portions 70. A connecting surface 42 is formed on the flat broken surface 71. A reflecting surface 41 is formed on the curved broken surface 72, protruding towards the LED die 30. The reflective cups 40 can be made by injection molding or pressing molding. A reflective layer (not illustrated) can be sprayed on the curved broken surface 72 before the reflective cup 40 is formed. A step of removing the buffer plate 60 can be preformed after step 5.

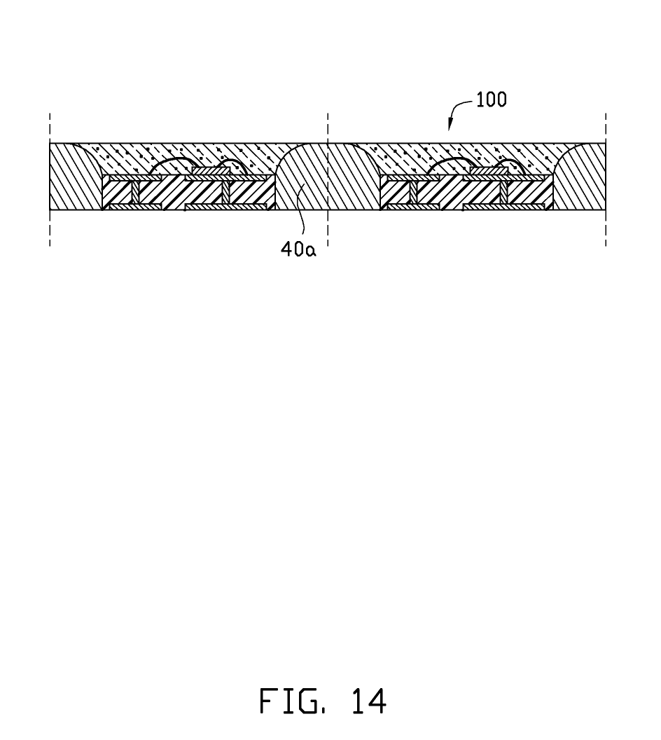

In step 6, referring to FIG. 14, the cutting is operated on the reflective cups 40a, thereby separating the plurality of reflective cups 40, thereby obtaining two LED packages 100, as shown in FIG. 1.

It is to be understood that the above-described embodiments are intended to illustrate rather than limit the disclosure. Variations may be made to the embodiments without departing from the spirit of the disclosure as claimed. The above-described embodiments illustrate the scope of the disclosure but do not restrict the scope of the disclosure.

What is claimed is:

1. An LED package, comprising:
a substrate;
a pair of electrodes formed on the substrate;
an LED die electrically connected to the electrodes;
an encapsulation formed on the substrate to cover the LED die; and
a reflective cup surrounding the substrate and the encapsulation, wherein the reflective cup comprises a curved surface abutting against and facing towards the encapsulation.

2. The LED package of claim 1, wherein the curved surface is a reflecting surface, the reflecting surface is convex and positioned above the substrate and surrounds the LED die with a receiving space defined above the substrate, and the reflecting surface protrudes towards the LED die and extends from the substrate upwardly and away from the LED die.

3. The LED package of claim 2, wherein the reflective cup further comprises a connecting surface extending downwardly from the reflecting surface.

4. The LED package of claim 3, wherein the connecting surface surrounds the substrate and is attached to lateral sides of the substrate.

5. The LED package of claim 1, wherein the substrate comprises four sidewalls, and a first recess and a second recess are defined in the substrate from one of the sidewalls towards an opposite sidewall.

6. The LED package of claim 5, wherein the substrate further comprises an upper surface and a lower surface connecting the sidewalls, and the first recess and the second recess penetrate the upper surface and the lower surface of the substrate.

7. The LED package of claim 6, wherein the electrodes comprise a first electrode and a second electrode, the first electrode covers an end of the first recess on the upper surface, and the second electrode covers an end of the second recess on the upper surface.

8. A method for manufacturing an LED package, the method comprising:
(a) providing a supporting board having a lower surface and an upper surface and forming a plurality of pairs of electrodes in the supporting board;
(b) electrically connecting a plurality of LED dies to the electrodes;
(c) forming an encapsulation to cover the LED dies on the supporting board;
(d) defining a plurality of depression portions from the lower surface of the supporting board to an upper surface of the encapsulation;
(e) forming reflective cups in the depression portions; and
(f) cutting the reflective cups to obtain individual LED dies.

9. The method for manufacturing the LED package of claim 8, wherein a plurality of recesses are defined at a lateral side of the supporting board in step (a).

10. The method for manufacturing the LED package of claim 9, wherein the electrodes 20 are formed on the upper surface and the lower surface of the supporting board.

11. The method for manufacturing the LED package of claim 8, wherein in step (d), the depression portions are formed by using a mold having a curved surface protruding downwardly to cut the supporting board and the encapsulation, and the curved surface is convex.

12. The method for manufacturing the LED package of claim 11, wherein the mold is positioned between two adjacent pairs of electrodes and the depression portions are formed by drilling the supporting board and the encapsulation from the lower surface of the supporting board.

13. The method for manufacturing the LED package of claim 12, wherein the mold moves in a substantially straight and downwardly direction in the supporting board to form a flat broken surface in the supporting board.

14. The method for manufacturing the LED package of claim 13, wherein the movement of the curved surface of the mold is stopped in the encapsulation to form a curved broken surface in the encapsulation.

15. The method for manufacturing the LED package of claim 12, wherein a step of covering a buffer plate on the encapsulation is performed before the step (d), and a step of removing the buffer plate is performed after the step (e).

16. The method for manufacturing the LED package of claim 15, wherein the buffer plate is attached on the upper surface of the supporting board, and the movement of the mold is stopped when the mold contacts the buffer plate.
